(19) United States
(12) Patent Application Publication
(10) Pub. No.: US 2025/0309084 A1
(43) Pub. Date: Oct. 2, 2025

(54) SEMICONDUCTOR PACKAGES WITH COMPACT LEAD DESIGN

(71) Applicant: TEXAS INSTRUMENTS INCORPORATED, Dallas, TX (US)

(72) Inventors: Hau NGUYEN, San Jose, CA (US); Lance WRIGHT, Allen, TX (US); Kurt SINCERBOX, San Jose, CA (US); Genki YANO, Beppu-Shi Oita-Ken (JP); ZuoHui CHEN, Chengdu (CN); Hao ZHANG, Chengdu (CN)

(21) Appl. No.: 18/622,547

(22) Filed: Mar. 29, 2024

(51) Int. Cl. H01L 23/498; H01L 23/00; H01L 23/31; H01L 25/00; H01L 25/065

(52) U.S. Cl. CPC H01L 23/49838; H01L 23/3107; H01L 23/49866; H01L 24/48; H01L 25/0655; H01L 25/50; H01L 24/16; H01L 24/94; H01L 2224/16245; H01L 2224/48245; H01L 2224/94; H01L 2924/1815

(57) ABSTRACT

In examples, a semiconductor package includes a copper lead having top and bottom surfaces, an end surface, and first and second lateral surfaces orthogonal to the top, bottom, and end surfaces. The end surface, the top surface, and the bottom surface are plated with another metal, a first portion of the first lateral surface distal to a mold compound and proximal to the end surface is plated with the another metal, a second portion of the first lateral surface distal to the mold compound and proximal to the first portion of the first lateral surface is not plated with the another metal, a first portion of the second lateral surface distal to the mold compound and proximal to the end surface is plated with the another metal, and a second portion of the second lateral surface distal to the mold compound and proximal to the first portion of the second lateral surface is not plated with the another metal.

### BACKGROUND

Semiconductor wafers are circular pieces of semiconductor material, such as silicon, that are used to manufacture semiconductor chips. Generally, complex manufacturing processes are used to form numerous integrated circuits on a single wafer. The formation of such circuits on a wafer is called fabrication. After wafer fabrication, the wafer is cut into multiple pieces, called semiconductor dies, with each die containing one of the circuits. The cutting, or sawing, of the wafer into individual dies is called singulation. An individual die is then coupled to a die pad and to conductive terminals, sometimes called “leads.” The resulting structure is subsequently covered with a mold compound to produce a package.

### SUMMARY

In examples, a semiconductor package comprises a semiconductor die having a device side in which circuitry is formed and a non-device side opposing the device side; a die pad coupled to the non-device side of the semiconductor die; a mold compound covering the semiconductor die and the die pad; and a copper lead having a first portion located inside the mold compound and a second portion located exterior to the mold compound, the first portion of the copper lead not plated by another metal. The second portion of the copper lead includes: top and bottom surfaces; an end surface distal to the first portion of the copper lead and facing away from the mold compound; and first and second lateral surfaces orthogonal to the top, bottom, and end surfaces. The end surface, the top surface, and the bottom surface are plated with another metal. A first portion of the first lateral surface distal to the mold compound and proximal to the end surface is plated with the another metal. A second portion of the first lateral surface proximal to the mold compound and distal to the end surface is not plated with the another metal. A first portion of the second lateral surface distal to the mold compound and proximal to the end surface is plated with the another metal. A second portion of the second lateral surface proximal to the mold compound and distal to the end surface is not plated with the another metal.

In examples, a method of manufacturing a semiconductor package comprises coupling a semiconductor die to a die pad of a lead frame, the die pad being in an area between first and second dam bars extending in parallel to each other. The die pad is coupled to a tie bar extending between the first and second dam bars. The lead frame includes a first lead having a proximal end in the area and a distal end in another area between the second dam bar and a third dam bar extending in parallel with the second dam bar. The distal end of the first lead faces and does not touch a distal end of a second lead. The second lead is coupled to the third dam bar. a connection bar connects the second and third dam bars to each other. The method also comprises wirebonding the semiconductor die to the first lead; covering the semiconductor die, the die pad, and the proximal end of the first lead with a mold compound; plating the first and second leads, including the distal ends of the first and second leads; and trimming the tie bar and the first and second dam bars and cutting the mold compound to produce the semiconductor package.

### BRIEF DESCRIPTION OF THE DRAWINGS

FIG. 1 is a flow diagram of a method for manufacturing a package with a compact lead design, in accordance with various examples.

FIGS. 2-11H are a process flow for manufacturing a package with a compact lead design, in accordance with various examples.

FIGS. 12A and 12B are schematic diagrams demonstrating the space-conserving benefits of a package with a compact lead design, in accordance with various examples.

FIG. 13 is a graph demonstrating the increase in units per lead frame strip achieved by the various examples described herein.

FIG. 14 is a block diagram of an electronic device, in accordance with various examples.

### DETAILED DESCRIPTION

Semiconductor packages typically include a die pad on which the semiconductor die is seated. Semiconductor packages also generally include multiple conductive terminals that provide electrical pathways between the semiconductor die inside the semiconductor package and electrical components (e.g., printed circuit boards (PCBs) and devices coupled to such PCBs) outside of the semiconductor package. During manufacture of the semiconductor package, the die pad and the conductive terminals are obtained from a structure called a lead frame, which is a metal structure that includes the die pad, the conductive terminals, and mechanical support structures (e.g., tie bars and dam bars) that support the die pad and the conductive terminals. Because semiconductor packages are mass-manufactured, lead frames are generally organized into lead frame strips, which can contain thousands of lead frames.

The architecture of a lead frame strip can significantly impact the efficiency of semiconductor package manufacture. It is generally desirable to maximize the number of lead frames, or “units,” that are included in a given area of a lead frame strip. For example, a lead frame strip having 100 units in an area x is generally considered superior to another lead frame strip having 50 units in the same area x, at least from an efficiency perspective. Some existing lead frame strip designs have highly inefficient architectures. For example, some lead frame strips include conductive terminals extending toward each other from neighboring die pads, and these conductive terminals are joined by a vertical member running along the length of the lead frame strip. The vertical member provides mechanical support to the conductive terminals and to the die pads, but the vertical member also occupies an unacceptably high amount of space in the lead frame strip. Other lead frame strip architectures attempt to solve this problem by replacing the vertical member with interdigitated conductive terminals, where a first conductive terminal extends from a first die pad toward a second die pad neighboring the first die pad, and a second conductive terminal immediately adjacent to the first conductive terminal extends from the second die pad toward the first die pad. Such a design is disadvantageous at least because the interdigitation increases the minimum pitch that is possible between consecutive conductive terminals on each die pad. Thus, with such designs, low-pitch semiconductor packages are not possible. A lead frame strip architecture that resolves these technical challenges is desirable.

This disclosure describes various examples of a lead frame strip architecture that resolves the technical challenges described above. This disclosure also describes various examples of semiconductor packages manufactured using such lead frame strip architectures, as well as methods for manufacturing such semiconductor packages. The lead frame strip architecture described herein includes first, second, third, and fourth dam bars extending in parallel with each other. The lead frame strip includes a first tie bar coupled to the first and second dam bars and a second tie bar coupled to the third and fourth dam bars. A tic bar is a metal component of a lead frame or lead frame strip that provides structural support to one or more other components, such as to a die pad. A dam bar is a metal component of a lead frame or lead frame strip that prevents mold compound flow beyond the dam bar. The lead frame strip includes a first die pad located in an area between the first and second dam bars and coupled to the first tie bar, and a second die pad located in an area between the third and fourth dam bars and coupled to the second tie bar. The lead frame strip includes a first lead coupled to the first dam bar and extending toward the first die pad, and a second lead coupled to the second dam bar and extending toward the first die pad. The second lead has a distal end located in a space between the second and third dam bars. The lead frame strip includes a third lead coupled to the third dam bar and extending toward the second die pad, where the third lead has a distal end located in the space between the second and third dam bars. The distal ends of the second and third leads face each other and do not contact each other. The lead frame strip includes a fourth lead coupled to the fourth dam bar and extending toward the second die pad, and a connection bar connecting the second and third dam bars to each other.

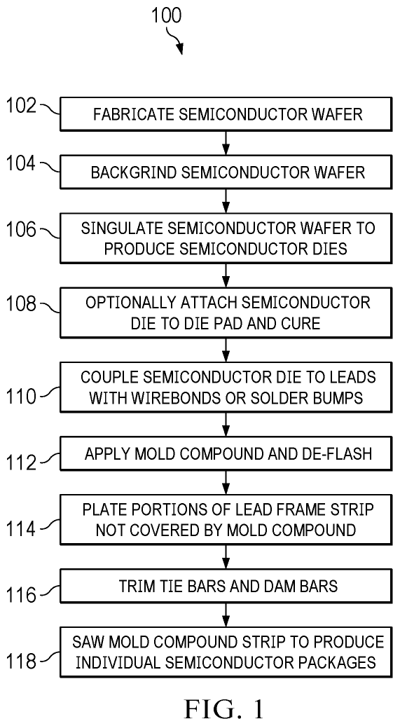

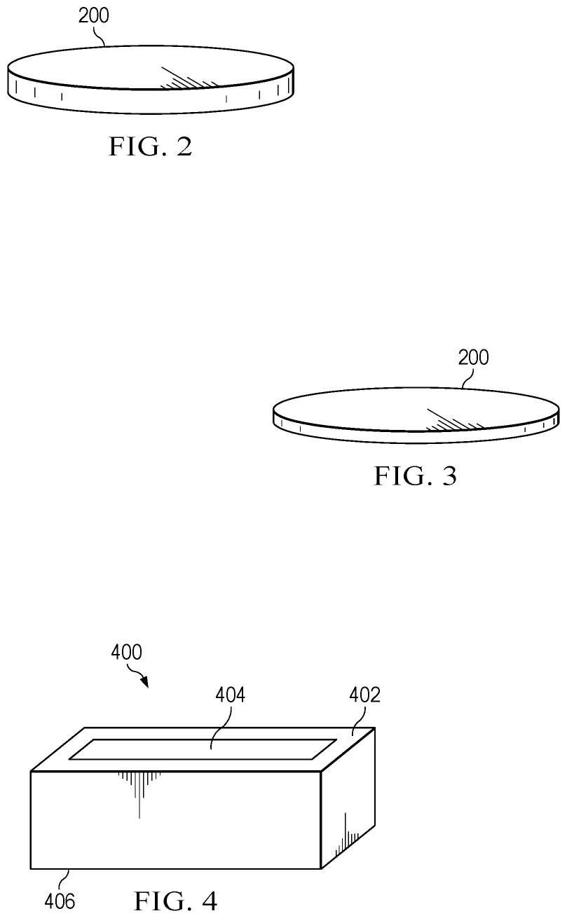

FIG. 1 is a flow diagram of a method for manufacturing a package with a compact lead design, in accordance with various examples. FIGS. 2-11G are a process flow for manufacturing a package with a compact lead design, in accordance with various examples. Accordingly, FIGS. 1 and 2-11G are now described in parallel. In particular, method 100 of FIG. 1 comprises fabricating a semiconductor wafer (102). The wafer may be fabricated to include any of a variety of circuitry, depending on the particular application in which the semiconductor dies formed from the semiconductor wafer will be deployed. FIG. 2 is a perspective view of an example semiconductor wafer 200. In examples, the semiconductor wafer 200 is a silicon wafer, although other types of semiconductor materials, such as silicon carbide, gallium nitride, etc., are contemplated and included in the scope of this disclosure. The method 100 further comprises back grinding the semiconductor wafer to reduce the thickness of the semiconductor wafer (104). FIG. 3 is a perspective view of the semiconductor wafer 200 having been back grinded, resulting in a thinner wafer than is depicted in FIG. 2. “Back grinding” is the grinding of the backside, or non-device side, of the semiconductor wafer 200 in which circuitry is not formed. Stated differently, the device side of the semiconductor wafer in which circuitry is formed is not grinded.

The method 100 includes singulating the semiconductor wafer to produce individual semiconductor dies (106). FIG. 4 is an example semiconductor die 400 produced by singulating the back grinded semiconductor wafer 200 of FIG. 3. The semiconductor die 400 includes a device side 402 in which circuitry 404 is formed. The circuitry 404 may be configured to perform any of a variety of operations, as described above. The semiconductor die 400 also includes a non-device side 406 opposing the device side 402.

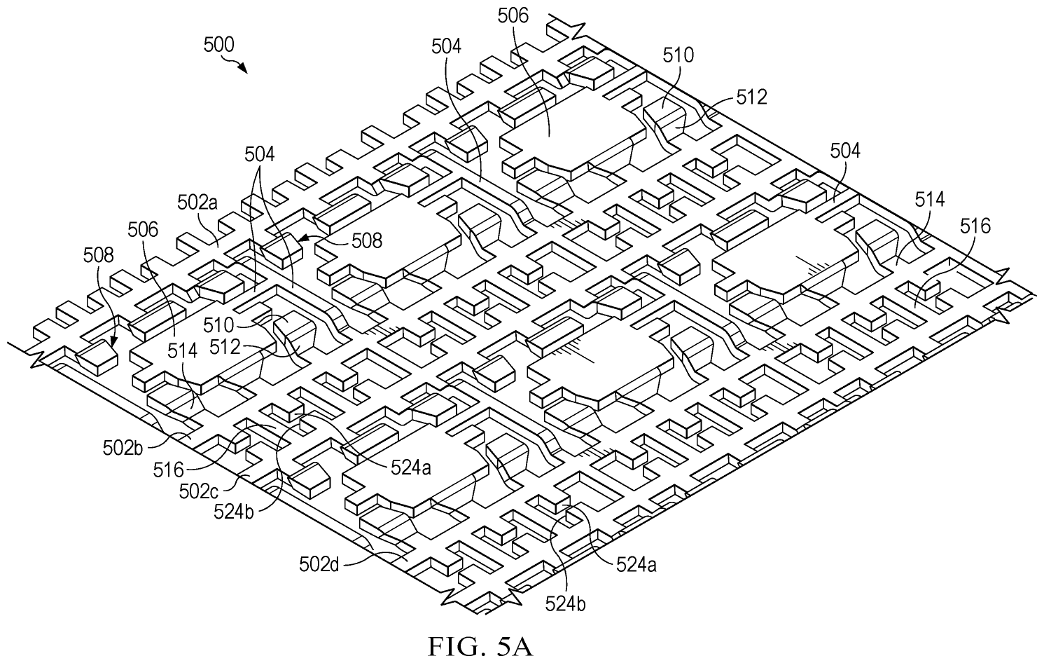

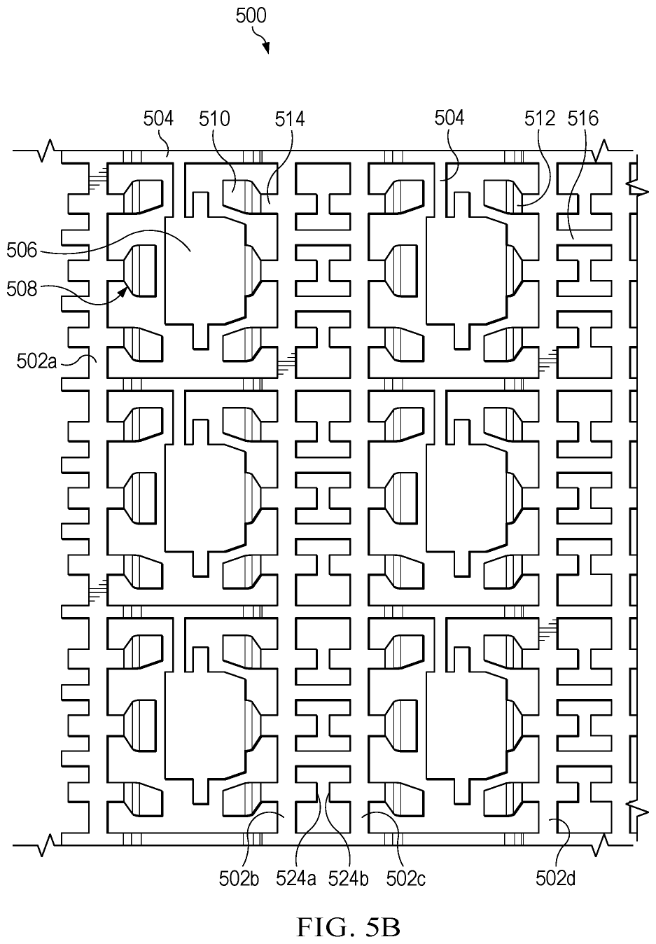

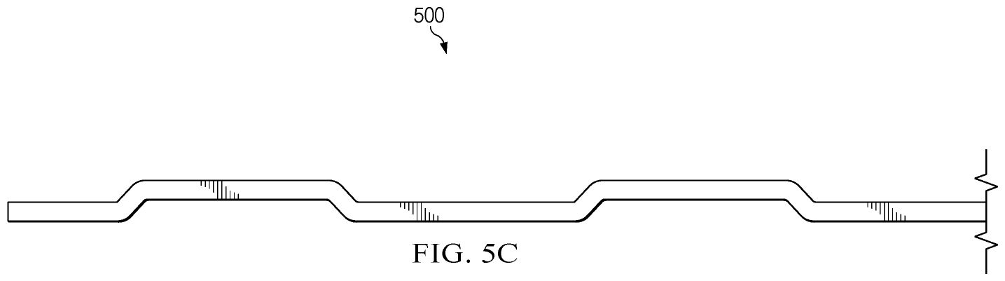

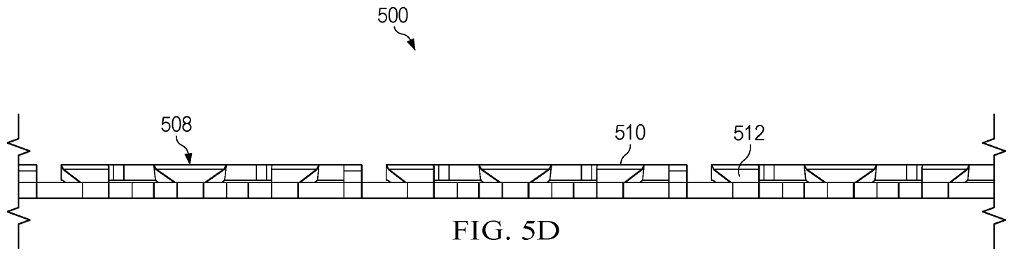

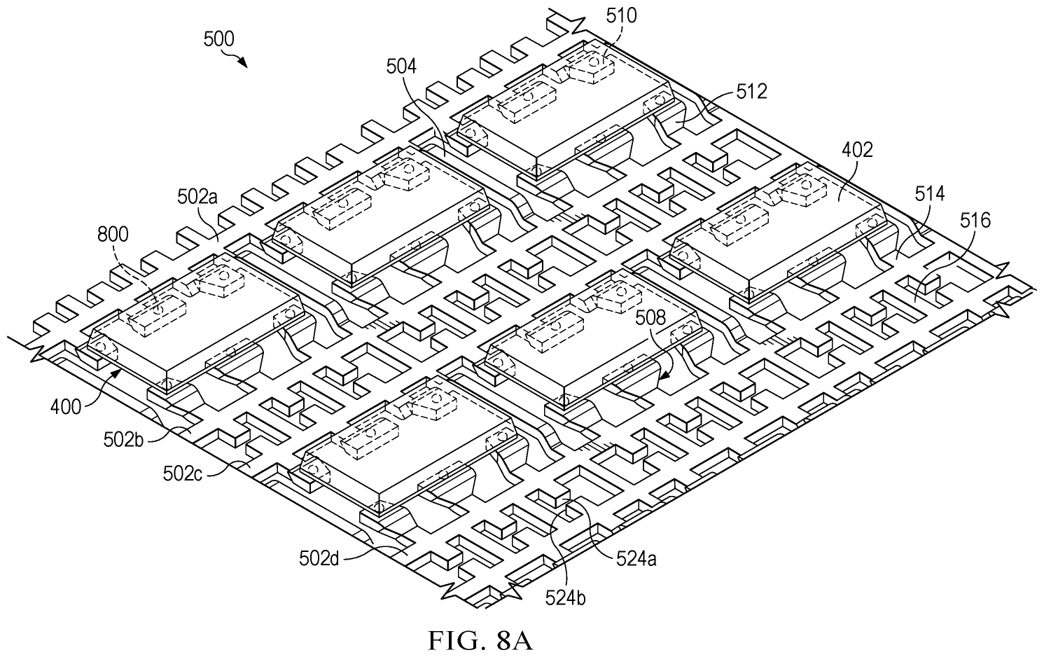

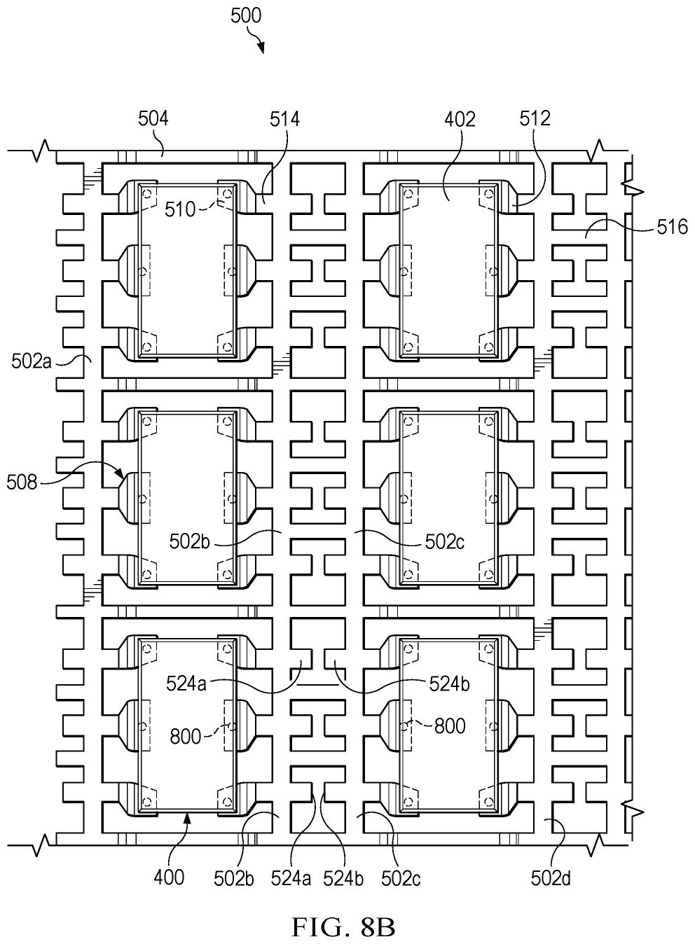

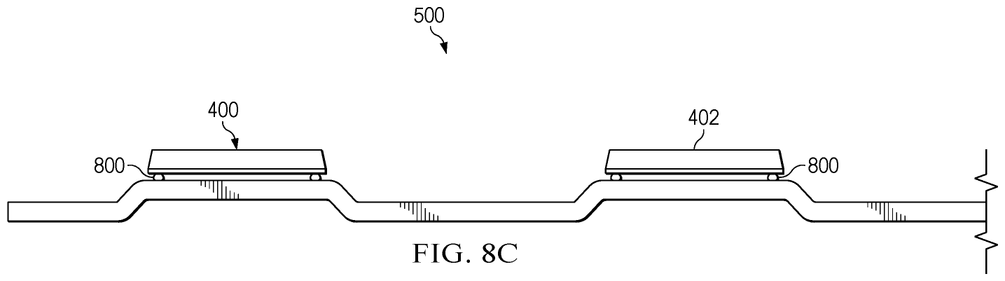

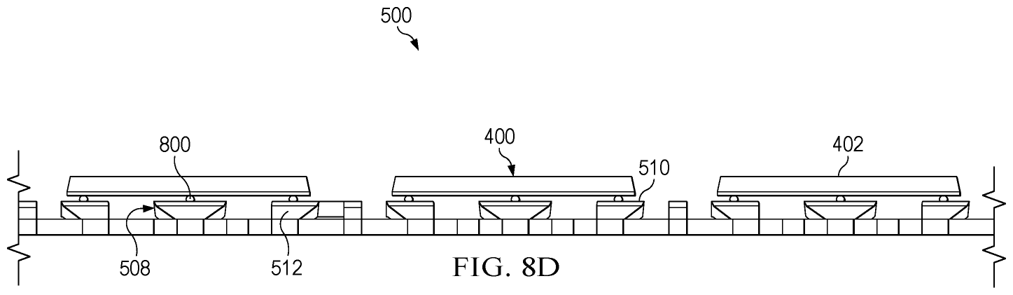

The method 100 includes optionally coupling the semiconductor die to a die pad and curing the die attach material (108). FIG. 5A depicts a lead frame strip 500, in accordance with various examples. The example lead frame strip 500 provides the technical advantages described above and is useful for manufacturing semiconductor packages as described herein. The lead frame strip 500 may include any number of columns, with each column including any number of lead frames, or “units.” Each lead frame, or unit, includes a die pad, a tie bar connecting the die pad to mechanical supports, and multiple conductive terminals (e.g., leads). Such lead frames are useful for semiconductor packages that include wire bonds connecting the semiconductor dies 400 to respective conductive terminals. In other examples, such as depicted in FIG. 8A and described below, the lead frames, or units, may omit die pads, but may include the multiple conductive terminals. Such lead frames are useful for semiconductor packages in which the semiconductor die 400 is oriented facing downward in a “flip-chip” configuration, and the device side 402 of the semiconductor die 400 is coupled directly to the conductive terminals using solder bumps.

Referring still to FIG. 5A, the lead frame strip 500 may comprise any suitable metal, such as copper. The lead frame strip 500 includes dam bars 502a, 502b, 502c, and 502d. Each pair of dam bars extends along the length of a column that contains multiple lead frames. For example, the dam bars 502a and 502b extend approximately parallel to each other and lengthwise along the column in between the dam bars 502a and 502b, and that column between the dam bars 502a and 502b may contain any number of lead frames in series. Similarly, dam bars 502c and 502d extend approximately parallel to each other and lengthwise along the column in between the dam bars 502c and 502d, and that column between the dam bars 502c and 502d may contain any number of lead frames in series.

The dam bars 502a, 502b are connected to each other by a tie bar 504. The tic bar 504 may extend orthogonally to the dam bars 502a, 502b, for example. The tic bar 504 extends across the column defined by the dam bars 502a, 502b to connect the dam bars 502a, 502b to each other. The tic bar 504 also extends to couple to and mechanically support a die pad 506. Multiple conductive terminals 508 (e.g., leads) extend toward the die pad 506, as shown. Each conductive terminal 508 includes a proximal segment 510 (also referred to herein as an “elevated portion”), a connecting segment 512 (i.e., a sloping portion) coupled to the proximal segment 510, and a distal segment 514 coupled to the connecting segment 512. The proximal segment 510 and the distal segment 514 are flat, horizontally-oriented segments, while the connecting segment 512 extends at an angle between the proximal segment 510 and the distal segment 514. A portion of the distal segment 514 couples to a respective dam bar, such as dam bars 502a-502d. Further, each conductive terminal 508 includes a proximal end and a distal end, where the proximal end is closest to the respective die pad 506, and the distal end is farthest from the respective die pad 506. A distal end 524a (also referred to herein as an “end surface”) of a first conductive terminal 508 is positioned in an area between the dam bars 502b, 502c, and a distal end 524b (or “end surface”) of a second conductive terminal 508 is positioned in the area between the dam bars 502b, 502c, with the distal ends 524a, 524b facing each other. Other pairs of conductive terminals 508 similarly have distal ends in between respective dam bars, with the distal ends facing each other. The distal ends 524a, 524b are separated by a gap ranging between 50 microns and 300 microns, with a distance greater than this range being disadvantageous because the lead frame density (i.e., number of lead frame units per area of lead frame strip) unacceptably decreases, and with a distance below this range being disadvantageous because there is not sufficient room for subsequent plating of the distal ends 524, 524b to occur. A connection bar 516 couples the dam bars 502b, 502c to each other. Similar connection bars couple other respective pairs of dam bars to each other. The connection bar 516 may extend orthogonally relative to dam bars 502b, 502c.

In examples, the die pad 506 is up-set, meaning that the die pad 506 is positioned vertically higher than the dam bars 502a-502b, and higher than the distal segments 514. The proximal segments 510, as well as the proximal ends, are vertically the same height from the dam bars 502a-502b as is the die pad 506.

The architecture of the lead frame strip 500 provides various advantages. For example, the vertical member found in between conductive terminals in existing solutions, as described above, is omitted from the lead frame strip 500. Instead of using such a vertical member to join adjacent dam bars and/or conductive terminals, the lead frame strip 500 includes the connection bar 516, which operates to provide the mechanical support formerly provided by the vertical member. The connection bar 516 is useful at least because it occupies significantly less space than the vertical member in existing solutions, and thus the connection bar 516 enables adjacent conductive terminals (and more specifically, distal ends 524a, 524b that are facing each other) to be brought significantly closer together than would otherwise be possible in solutions having the aforementioned vertical member. Because the distal ends 524a, 524b can be brought closer together, and generally because the connection bar 516 reduces the amount of space needed relative to the vertical member in existing solutions, more lead frame units can be included in a given area of lead frame strip than is possible with the existing lead frame architectures. Stated differently, because the connection bar 516 occupies less space, the density of the lead frame strips can be significantly increased. Furthermore, avoiding interdigitation of the conductive terminals 508 results in the ability to bring the conductive terminals of each lead frame unit closer together, thereby decreasing the minimum pitch that is possible between immediately adjacent (i.e., consecutive) conductive terminals 508. This minimum pitch is less than 2.5 mm. Further still, the conductive terminals 508 are separated between dam bars 502b, 502c (and between other respective pairs of dam bars as well) before the semiconductor package manufacturing process 100 begins. Stated differently, the gap between the distal ends 524a, 524b exists prior to starting the semiconductor package manufacturing process 100. Consequently, when the lead frame strip is plated later, the distal ends 524a, 524b are plated, as are most surfaces of the distal segments 514. This specific plating pattern results in superior solder wettability when the semiconductor package is later mounted to a printed circuit board (PCB), and relatedly, results in significantly easier optical inspection opportunities as well. Further still, the up-set die pads 506 can be advantageous because they can be covered on all sides by mold compound, which is useful in applications in which it is undesirable for the die pads 506 to be exposed. The up-set die pads 506 can also make it easier for the lead frame strip 500 to rest on a pedestal during the wire bonding process. Further still, the shape of the conductive terminals 508 (i.e., a flat, horizontal distal segment 514, an angled connecting segment 512, and a flat, horizontal proximal segment 510) forms a “hook” shape that forms a strong and stable connection within the mold compound when the mold compound is applied.

The foregoing description applies primarily to one lead frame unit in the lead frame strip 500. The lead frame strip 500 may include any number of such lead frame units, and the foregoing description applies to all such lead frame units.

FIG. 5B is a top-down view of the structure of FIG. 5A, in accordance with various examples. FIG. 5C is a profile view of the structure of FIG. 5A, in accordance with various examples. FIG. 5D is another profile view of the structure of FIG. 5A, in accordance with various examples.

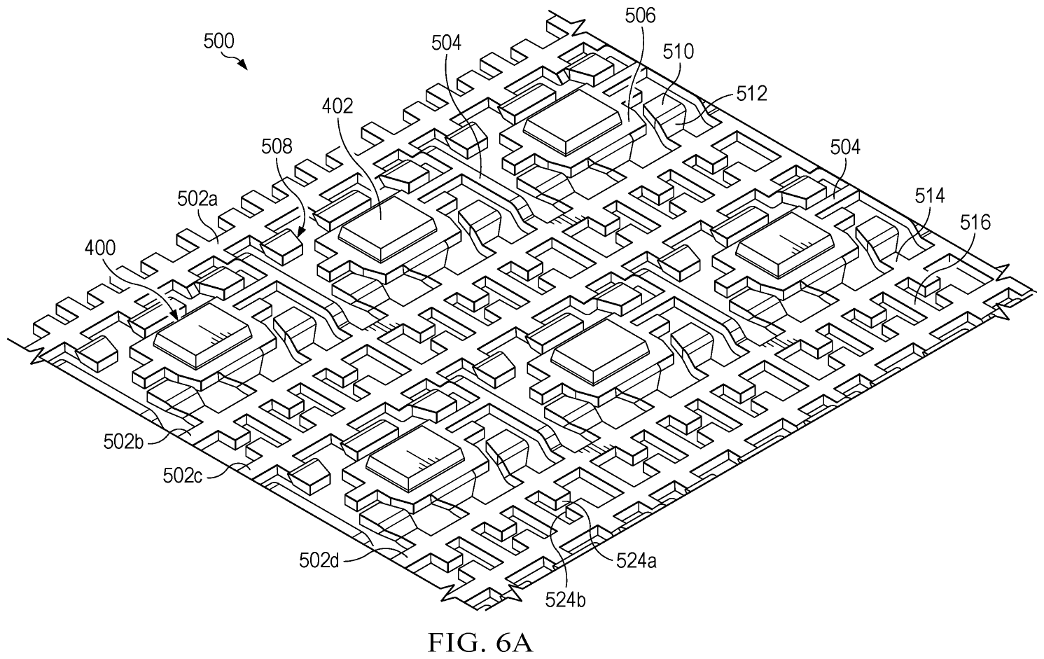

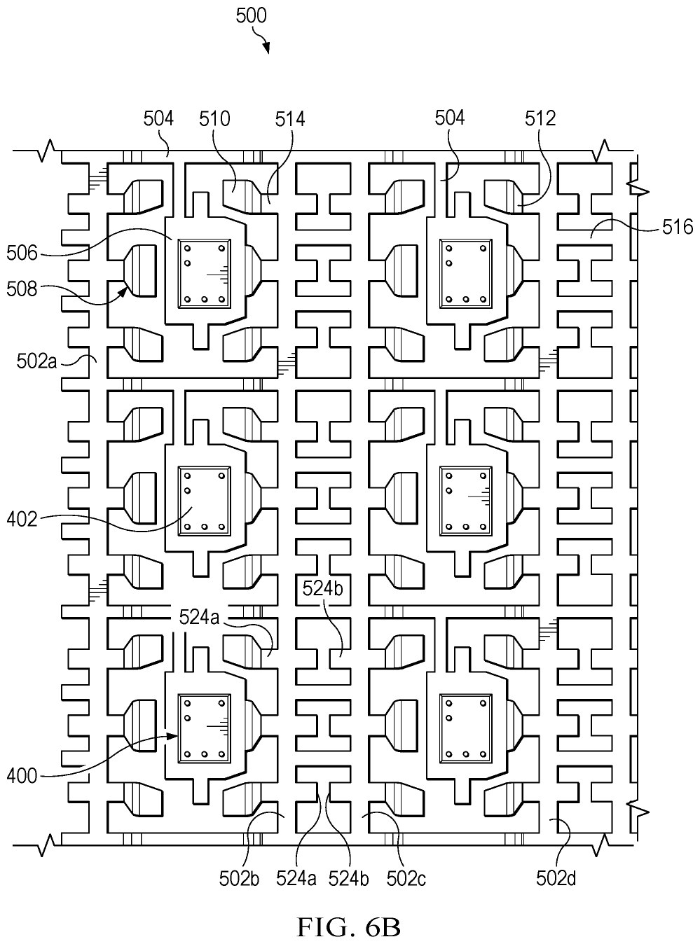

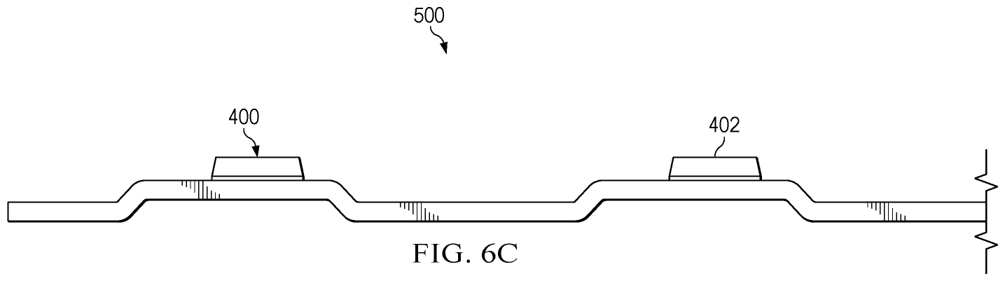

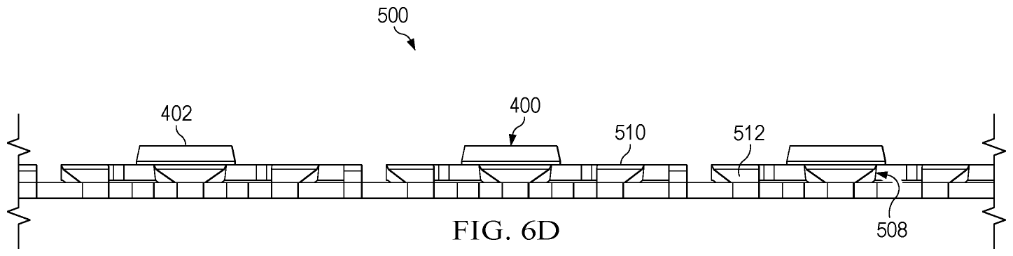

FIG. 6A is a perspective view of the structure of FIG. 5A in accordance with various examples, except that FIG. 6A additionally includes semiconductor dies 400 coupled to the die pads 506. The semiconductor dies 400 may be coupled to the die pads 506 by suitable die attach material, which is then cured to form a strong connection between the semiconductor dies 400 and the respective die pads 506. FIG. 6B is a top-down view of the structure of FIG. 6A, in accordance with various examples. FIG. 6C is a profile view of the structure of FIG. 6A, in accordance with various examples. FIG. 6D is another profile view of the structure of FIG. 6A, in accordance with various examples.

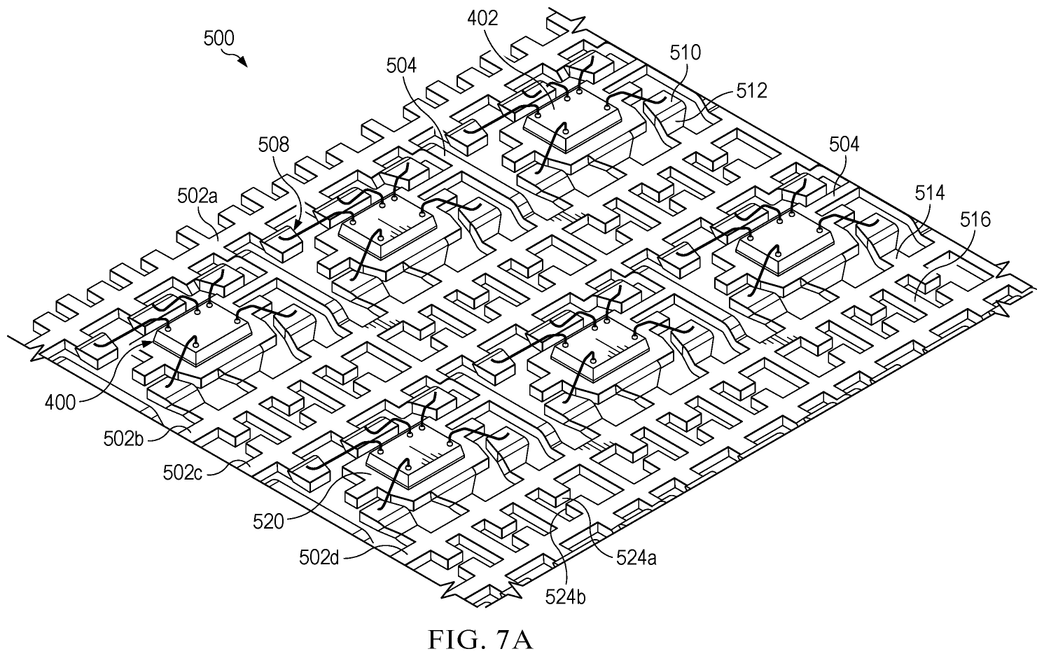

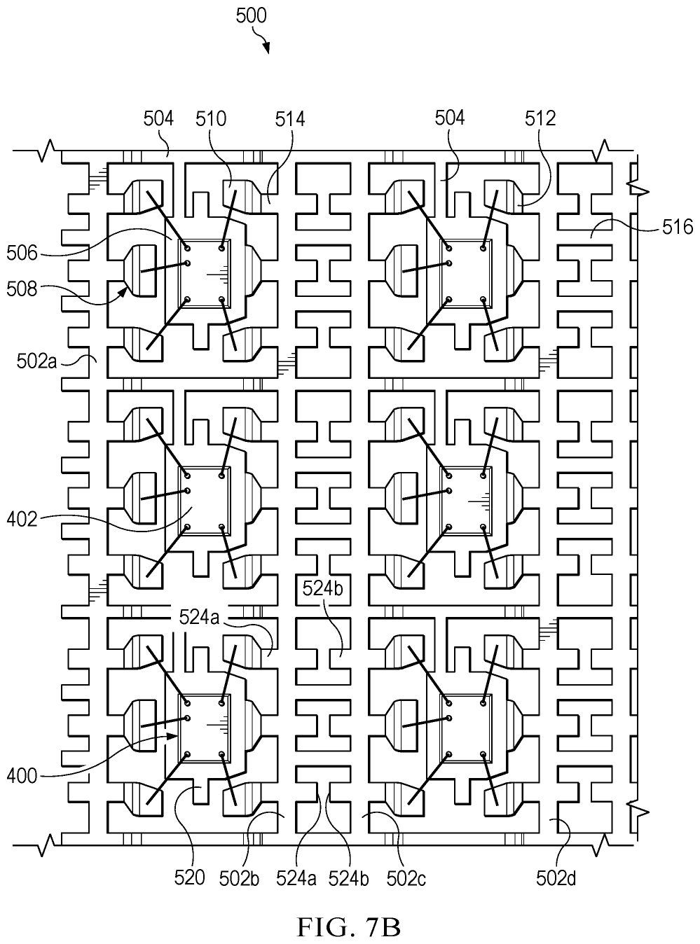

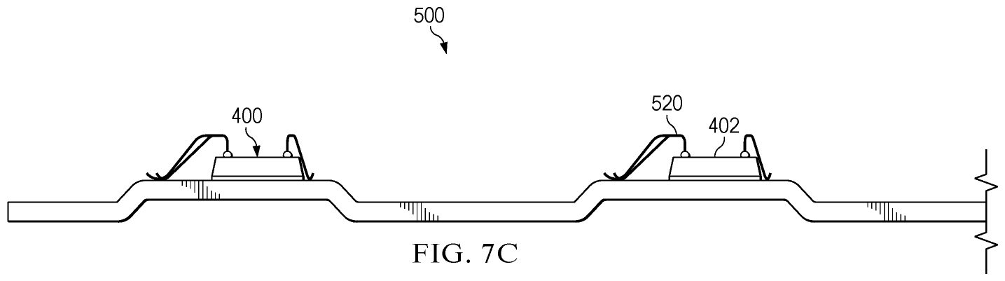

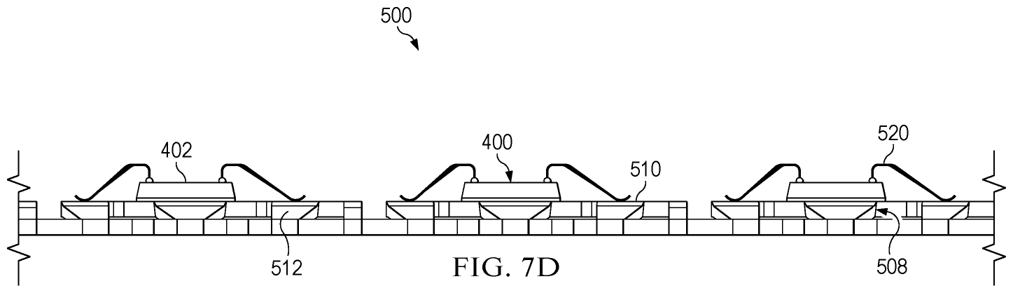

The method 100 includes coupling the semiconductor die to leads with wire bonds or solder bumps (110). FIG. 7A is a perspective view of the structure of FIG. 6A in accordance with various examples, except that in FIG. 7A, the semiconductor dies 400 have been wire bonded to respective conductive terminals 508, as shown. More specifically, the device sides 402 of the semiconductor dies 400 are wire bonded to the proximal segments 510 of the conductive terminals 508. In examples, a ball bond may be formed on the semiconductor die 400 (e.g., on bond pads of the semiconductor die 400), and stitch bonds may be formed on the conductive terminals 508, although the scope of this disclosure is not limited to any particular wire bonding technique.

The description provided herein of the method 100 assumes that die pads 506 and wire bonding techniques are used to mount and electrically connect the semiconductor dies 400 to the lead frame strip 500. However, in some examples, a “flip-chip” configuration may be used, in which the device side 402 of the semiconductor die 400 is oriented facing downward, and solder bumps are used to couple the device side 402 of the semiconductor die 400 to the proximal segments 510 of the conductive terminals 508 in lieu of wire bond 520. FIG. 8A is a perspective view of the structure of FIG. 7A, except that instead of using die pads 506 and wire bonds 520 to couple semiconductor dies 400 to the lead frame strip 500, the semiconductor dies 400 are coupled to respective conductive terminals 508 using solder bumps 800. In this way, the conductive terminals 508 provide both mechanical support, which is provided by the die pad 506 in FIG. 7A, and electrical pathways, which are provided by the conductive terminals 508 in FIG. 7A. FIG. 8B is a top-down view of the structure of FIG. 8A, in accordance with various examples. FIG. 8C is a profile view of the structure of FIG. 8A, in accordance with various examples. FIG. 8D is another profile view of the structure of FIG. 8A, in accordance with various examples.

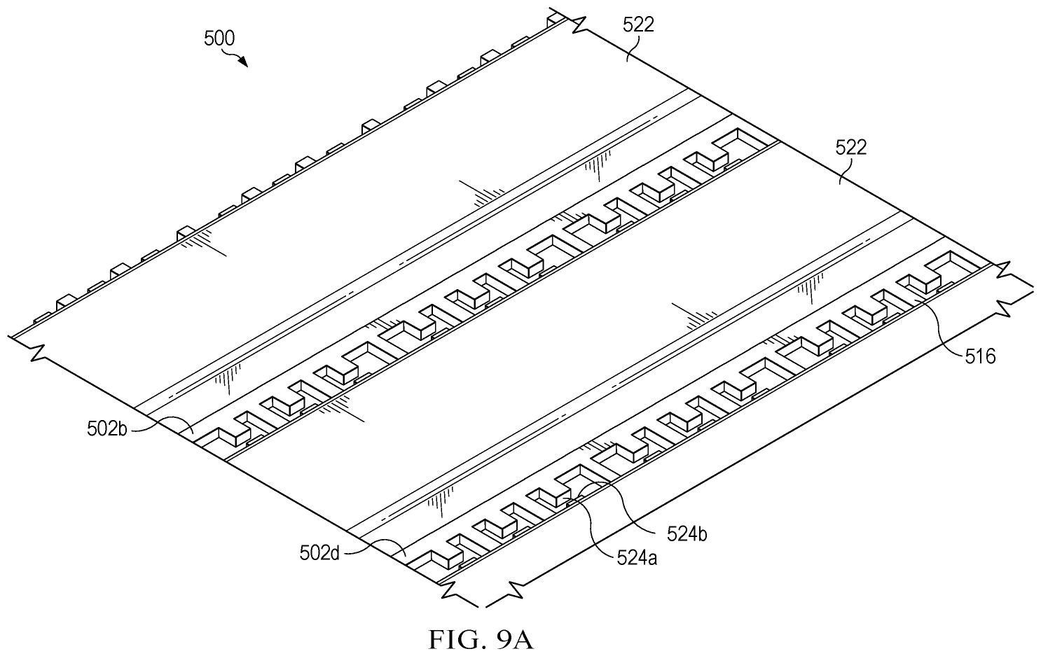

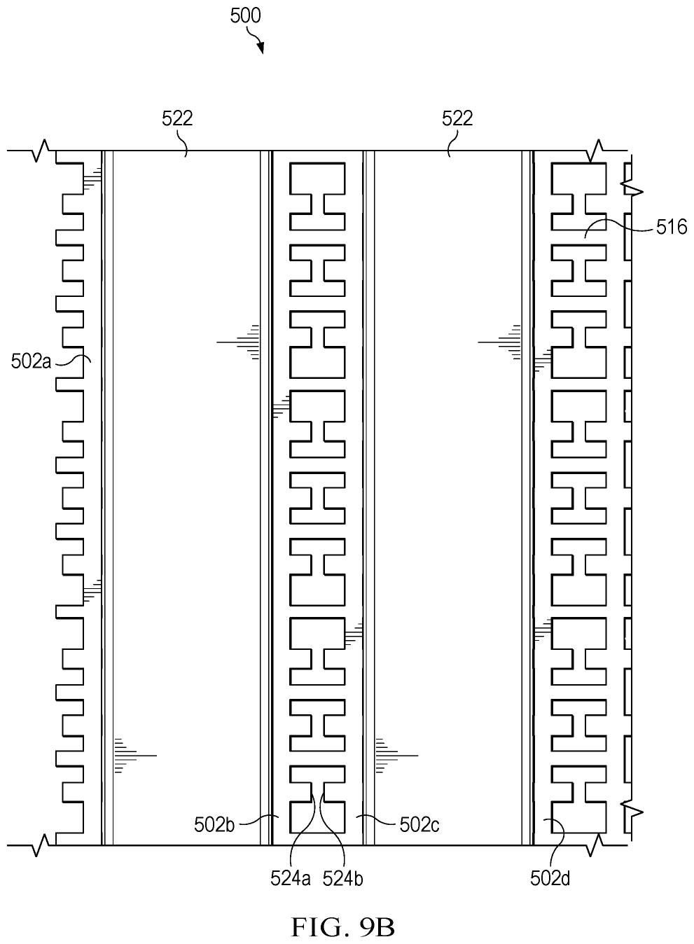

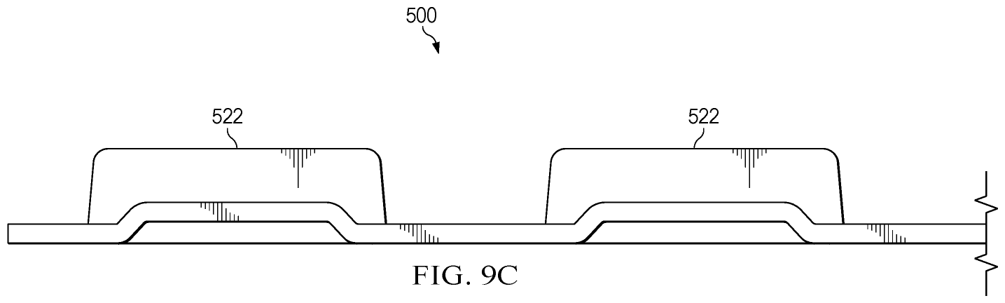

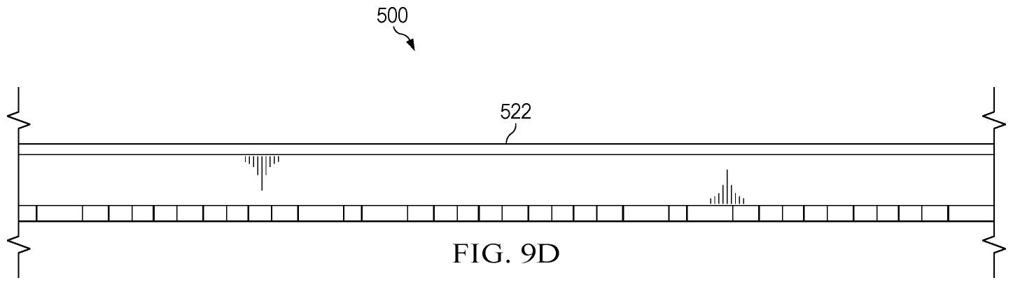

The method 100 comprises applying mold compound and performing a de-flash process (112). FIG. 9A is a perspective view of the structure of FIG. 7A, except that a mold compound 522 has been applied in each column of the lead frame strip 500. In examples, a mold chase may be useful to inject or otherwise apply the mold compound 522. The mold compound 522 may flow on and around the structures in each column to cover the structures. The dam bars 502a-502d prevent flow into the areas between columns, such as the area between dam bars 502b and 502c, for example. In this manner, step 112 forms multiple mold compound strips, one mold compound strip in each column of the lead frame strip 500. A de-flashing technique may be performed as well. FIG. 9B is a top-down view of the structure of FIG. 9A, in accordance with various examples. FIG. 9C is a profile view of the structure of FIG. 9A, in accordance with various examples. FIG. 9D is a profile view of the structure of FIG. 9A, in accordance with various examples.

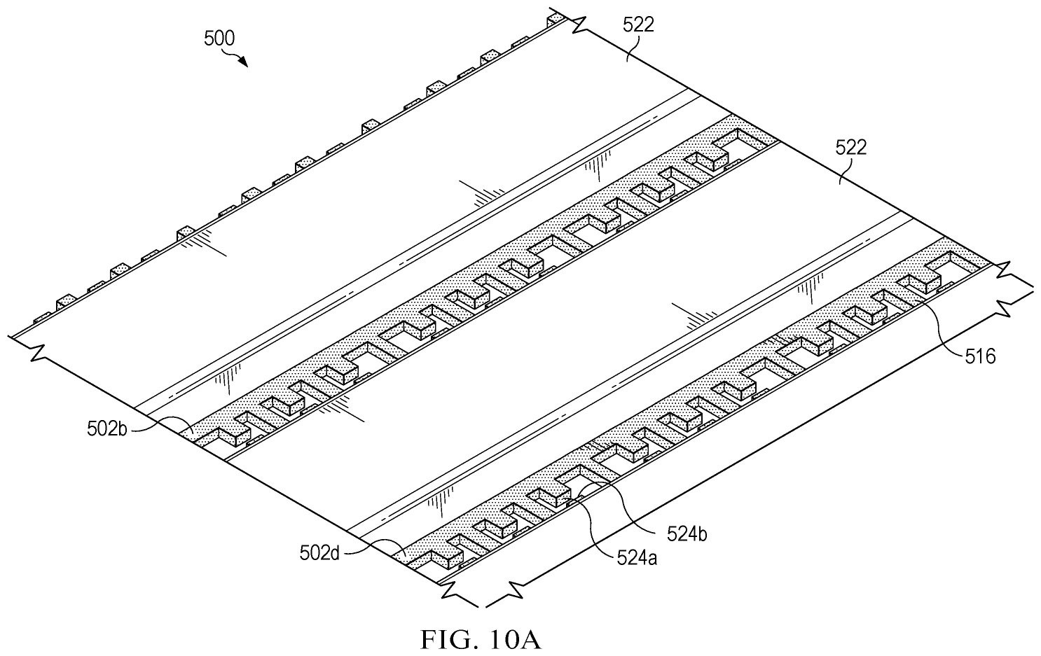

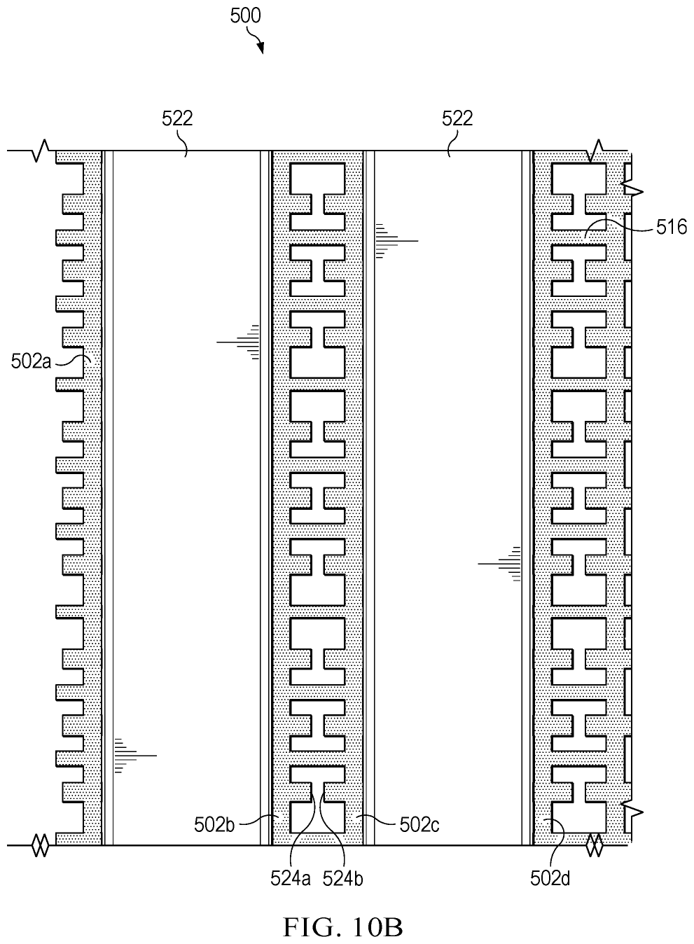

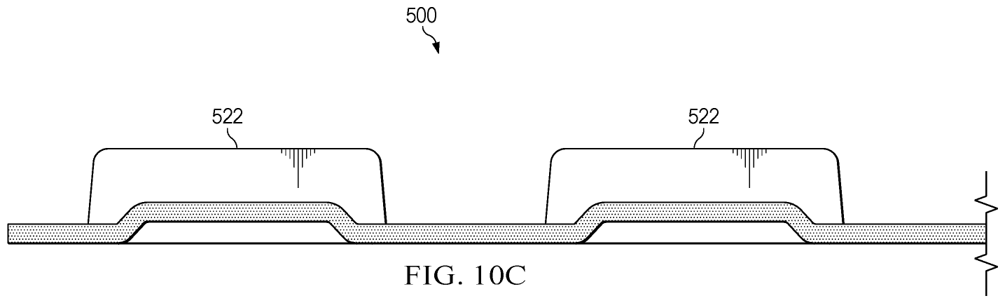

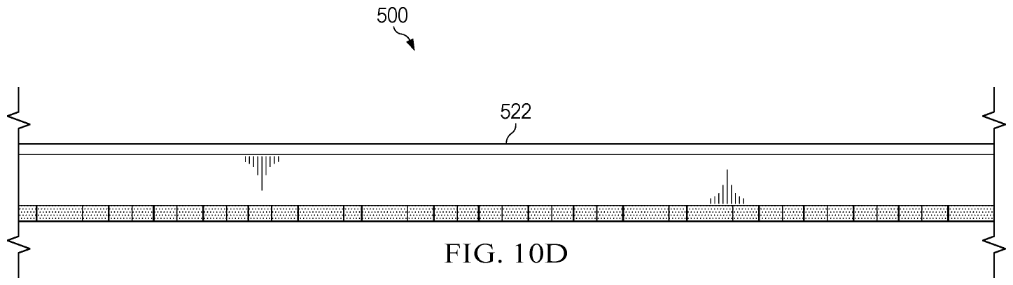

The method 100 includes plating portions of the lead frame strip not covered by mold compound (114). FIG. 10A is a perspective view of the structure of FIG. 9A, except that the areas of the lead frame strip 500 that are uncovered (i.e., all areas of the lead frame strip 500 except for those covered by the mold compound 522 and those covered by the dam bars, such as dam bar 502b) are plated with a suitable metal, such as tin. FIG. 10B is a top-down view of the structure of FIG. 10A, in accordance with various examples. FIG. 10C is a profile view of the structure of FIG. 10A, in accordance with various examples. FIG. 10D is another profile view of the structure of FIG. 10A, in accordance with various examples.

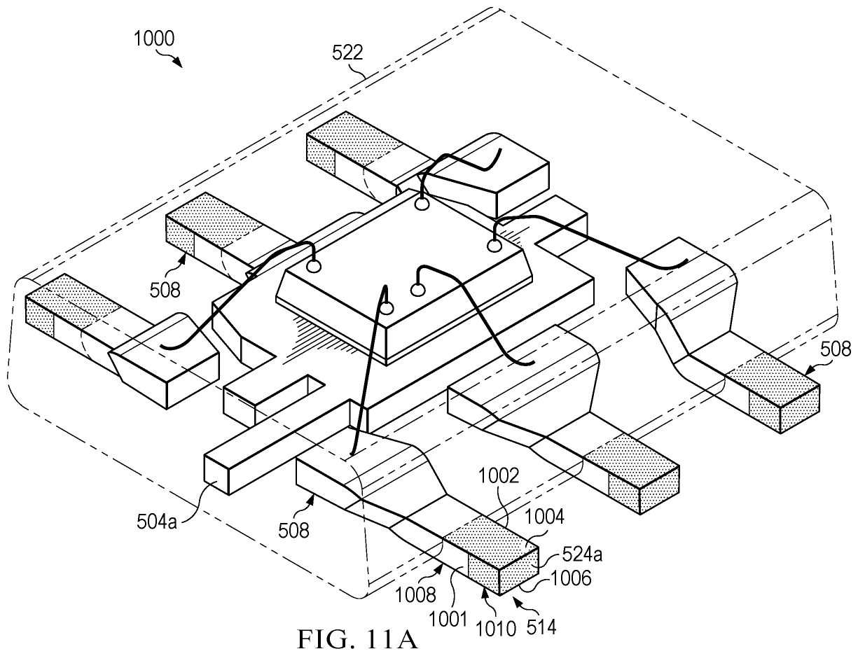

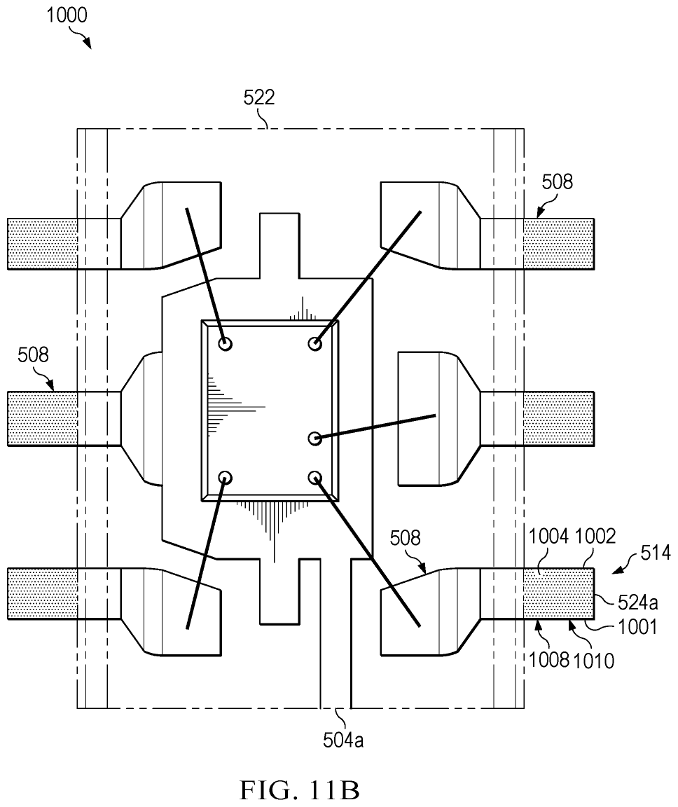

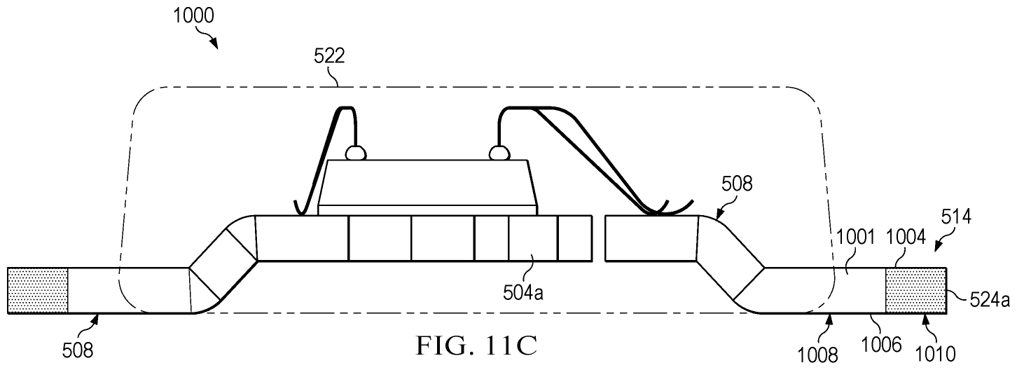

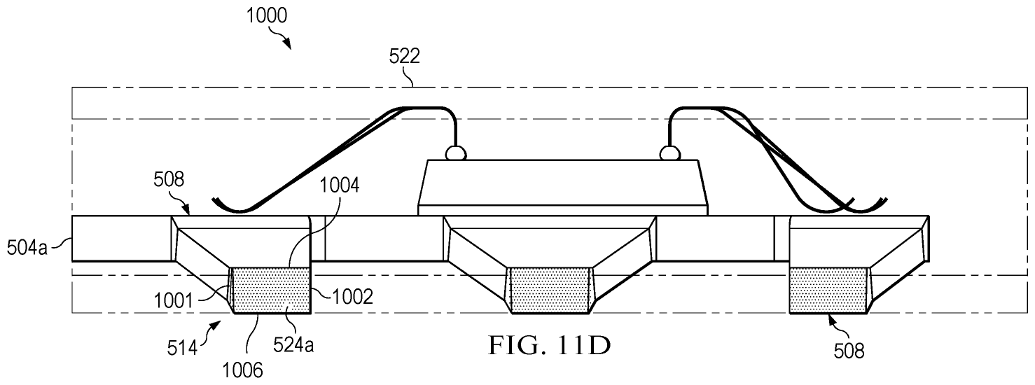

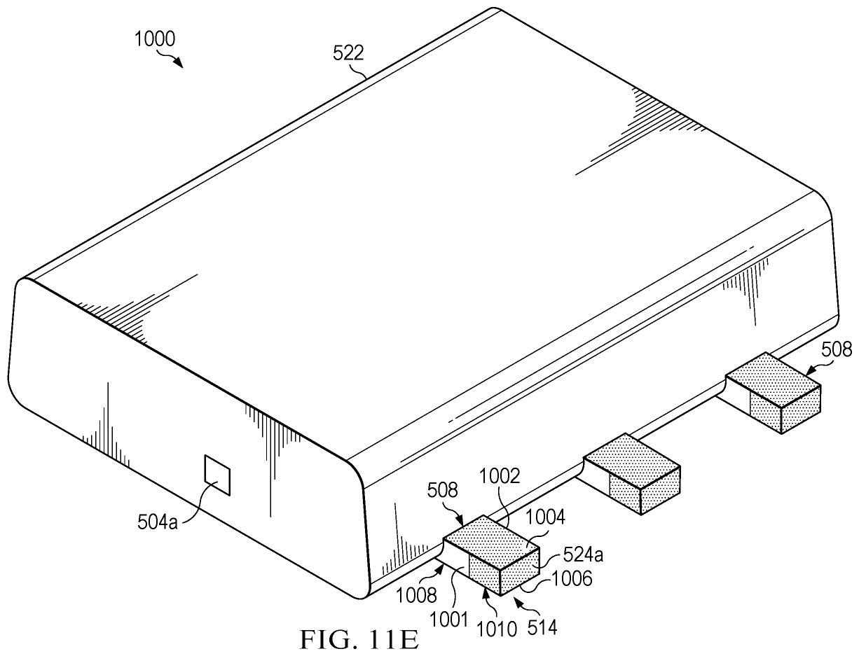

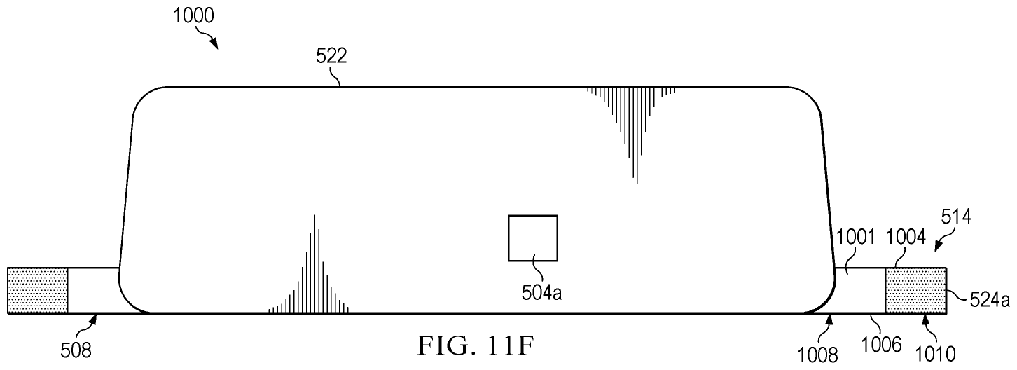

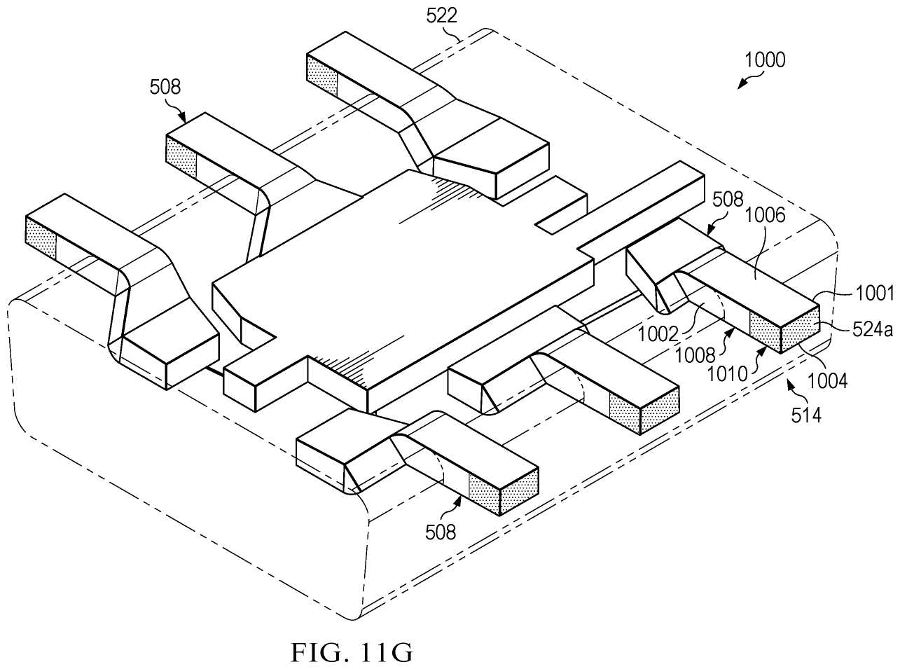

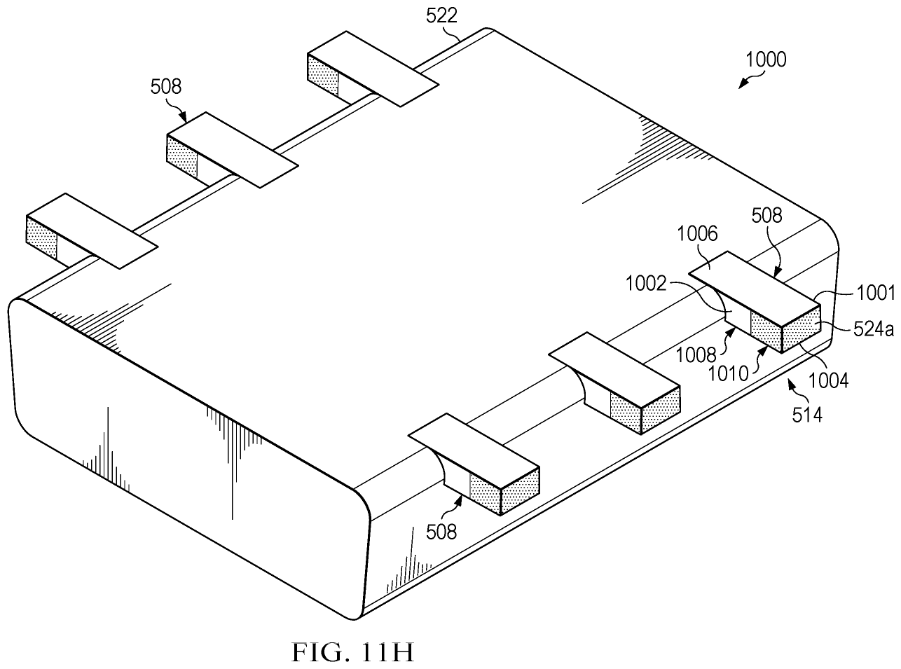

The method 100 also includes trimming the tic bars and dam bars (116), and sawing the mold compound strip to produce individual semiconductor packages (118). FIG. 11A is a perspective, see-through view of a completed semiconductor package 1000 after completion of steps 116 and 118, in accordance with various examples. The semiconductor package 1000 includes the conductive terminals 508, which extend from within the mold compound 522 to the exterior of the mold compound 522. Although six conductive terminals 508 are shown, any suitable number of conductive terminals 508 may be included. The distal segment 514 of each conductive terminal 508 includes a lateral surface 1001, a lateral surface 1002 opposing the lateral surface 1001, a top surface 1004, a bottom surface 1006 opposing the top surface 1004, and a distal end 524a. As can be seen, all surfaces of the distal segment 514 that were not covered during the plating process (i.e., that were not covered by the mold compound 522 or, alternatively, by virtue of connection with a dam bar such as dam bar 502b) are plated. However, the portions of the distal segment 514 that were covered by a dam bar, such as dam bar 502b, during plating, are not plated. Similarly, portions of the lead frame unit that were covered by the mold compound 522 are not plated. For instance, on lateral surface 1001, a portion 1010 is plated, but a portion 1008, which was covered by the dam bar 502b during plating, is not plated. The lateral surface 1002, which is not visible in the view of FIG. 11A, has a similar plating pattern as the lateral surface 1001. Surfaces 1002, 1006 are completely plated, as they are fully uncovered during the plating process. Similarly, the distal end 524a is fully plated, as the distal end 524a is fully uncovered during the plating process. This high degree of plating on the conductive terminals 508, and particularly the plating at the distal end 524a and the portions of surfaces 1001, 1002, 1004, and 1006 near distal end 524a, facilitate significantly improved solder wettability, as described above. The tic bars and dam bars, such as tie bar 504 and dam bar 502b, arc trimmed after plating is complete, thus revealing the portions 1008 (FIG. 11A) and the end of the tic bar 504 (FIG. 11F). FIG. 11B is a top-down view of the structure of FIG. 11A, in accordance with various examples. FIG. 11C is a profile view of the structure of FIG. 11A, in accordance with various examples. FIG. 11D is a profile view of the structure of FIG. 11A, in accordance with various examples. FIG. 11E is a perspective view of the structure of FIG. 11A, except that the mold compound 522 is opaque, in accordance with various examples. FIG. 11F is a profile view of the structure of FIG. 11E, in accordance with various examples. FIG. 11G is a perspective view of the bottom of the semiconductor package 1000, in accordance with various examples. FIG. 11H is a bottom perspective view of the structure of FIG. 11G, in accordance with various examples.

FIG. 11A depicts the die pad 506 as being up-set, as described above. However, in some examples, the die pad 506 is not up-set; instead, the bottom surface of the die pad 506 is within 0.05 mm of being flush with the bottom surface of the mold compound 522. Stated differently, the proximal and distal ends of the conductive terminals 508 are vertically the same distance from the dam bars.

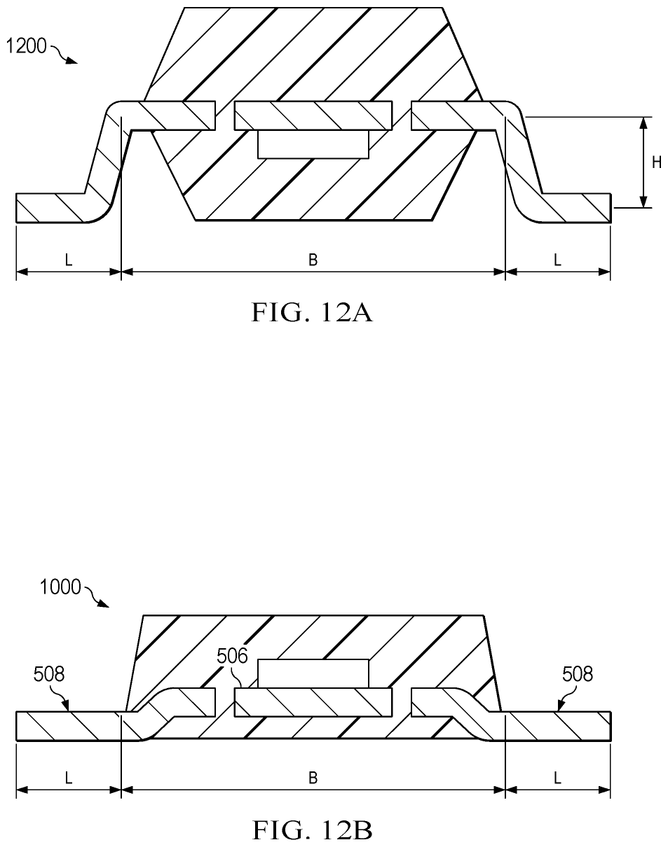

As described in detail above, various features of the lead frame strip 500 architecture improve lead frame strip density, thus increasing the number of lead frame units that can be included in a given area of lead frame strip. The lead frame strip density is increased even further because the “stub” lead design of the lead frame strip 500, in which the conductive terminals 508 are flat and do not require a bending or forming step (as would be the case with gullwing style leads), occupies less space in the lead frame strip 500 than gullwing style leads do. FIGS. 12A and 12B are schematic diagrams demonstrating the space-conserving benefits of a package with a compact lead design, in accordance with various examples. FIG. 12A depicts a traditional, gullwing-style leaded package 1200, and FIG. 12B depicts a semiconductor package 1000 in accordance with various examples. Referring to both FIGS. 12A and 12B, as can be seen, the conductive terminals 508 of the semiconductor package 1000 have the same footprint as do the gullwing-style leads of the package 1200. Because of the identical footprint, from an application perspective, the packages 1200 and 1000 are interchangeable. However, the total area of the conductive terminals and the die pad in the package 1200 is significantly greater than the total area of the conductive terminals 508 and the die pad 506 in the semiconductor package 1000. To determine the approximate area of the leads and the die pad in the package 1200, the length of each lead Lis doubled, the height of each lead H is doubled, and the body width B is added to these two products to produce a sum that is multiplied by the depth. The depth can be omitted in the calculation because the depth will be the same for both the packages 1200, 1000. To determine the approximate area of the leads and the die pad in the semiconductor package 1000, the length of each lead L is doubled and added to the body width B. However, the height of the conductive terminals 508 is negligible and can be ignored. Example calculations result in a total calculated area of 11.7 mm² for standard gullwing-style leaded packages such as the package 1200; a total calculated area of 10.44 mm² for inverted gullwing-style leaded packages; and a total calculated area of 8.12 mm² for the semiconductor package 1000. Consequently, the density of the lead frame strip 500 can be 44% greater than that for standard gullwing-style leaded packages such as package 1200, and can be 28% greater than that for inverted gullwing-style leaded packages.

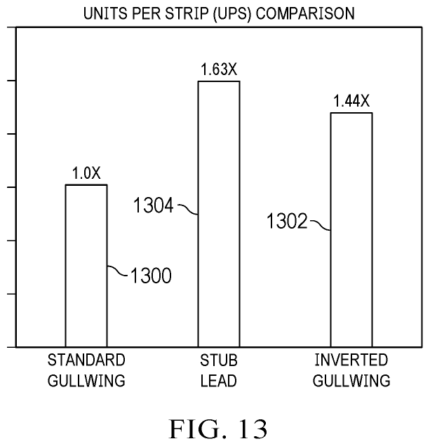

FIG. 13 is a graph demonstrating the increase in units per lead frame strip (UPS) achieved by the various examples described herein. Specifically, the improved architecture of the lead frame strip 500 can significantly increase the number of lead frame units that can be included in a lead frame strip of a given area. In the graph of FIG. 13, a constant lead frame strip size is assumed. Bar 1300 represents the units per strip achievable with a standard gullwing style package. Bar 1302 represents the units per strip achievable with an inverted gullwing style package. Bar 1304 represents the units per strip achievable by examples described herein. Although the inverted gullwing style package may achieve 1.44 times as many UPS as the standard gullwing style package (1302 vs. 1300), the examples described herein achieve at least 1.63 times as many UPS as the standard gullwing style package (1304 vs. 1300).

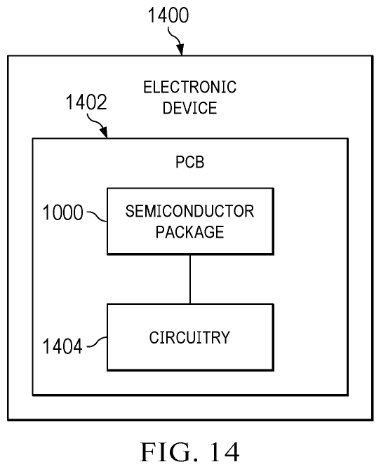

FIG. 14 is a block diagram of an electronic device, in accordance with various examples. An electronic device 1400 may include a smartphone, a laptop computer, a desktop computer, a notebook, a tablet, an appliance, any commercial electronic product, an automobile such as an electric vehicle, a watercraft, an aircraft, a spacecraft, etc. The electronic device 1400 may include a PCB 1402. A semiconductor package 1000 such as those described herein may be coupled to the PCB 1402. Circuitry 1404 may be coupled to the PCB 1402 and may operate to perform any of a variety of functions, possibly in tandem with the semiconductor package 1000.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be coupled to at least some of the passive elements and/or the sources to form the described structure either at a time of manufacture or after a time of manufacture, for example, by an end-user and/or a third-party.

In this description, unless otherwise stated, “about,” “approximately” or “substantially” preceding a parameter means being within +/−10 percent of that parameter. Modifications are possible in the described examples, and other examples are possible within the scope of the claims.

What is claimed is:

1. A semiconductor package, comprising:
a semiconductor die having a device side in which circuitry is formed and a non-device side opposing the device side;
a die pad coupled to the non-device side of the semiconductor die;
a mold compound covering the semiconductor die and the die pad; and
a copper lead having a first portion located inside the mold compound and a second portion located exterior to the mold compound, the first portion of the copper lead not plated by another metal, and the second portion of the copper lead including:
top and bottom surfaces;
an end surface distal to the first portion of the copper lead and facing away from the mold compound; and
first and second lateral surfaces orthogonal to the top, bottom, and end surfaces,
wherein the end surface, the top surface, and the bottom surface are plated with the another metal, a first portion of the first lateral surface distal to the mold compound and proximal to the end surface is plated with the another metal, a second portion of the first lateral surface distal to the mold compound and proximal to the first portion of the first lateral surface is not plated with the another metal, a first portion of the second lateral surface distal to the mold compound and proximal to the end surface is plated with the another metal, and a second portion of the second lateral surface distal to the mold compound and proximal to the first portion of the second lateral surface is not plated with the another metal.

2. The semiconductor package of claim 1, wherein the mold compound fully encapsulates the die pad such that the die pad is not visible from outside the mold compound.

3. The semiconductor package of claim 1, wherein the device side of the semiconductor die faces a top surface of the mold compound and the non-device side of the semiconductor die faces a bottom surface of the mold compound, and wherein the first portion of the copper lead includes an elevated portion that is closer to the top surface of the mold compound than is the second portion of the copper lead.

4. The semiconductor package of claim 3, wherein the first portion of the copper lead includes a sloping portion that connects the elevated portion to the second portion of the copper lead.

5. The semiconductor package of claim 1, wherein the second portion of the copper lead is flat.

6. The semiconductor package of claim 1, further comprising a second copper lead identical to the copper lead, wherein a pitch between the copper lead and the second copper lead is less than 2.5 mm.

7. The semiconductor package of claim 1, wherein the bottom surface of the copper lead is within 0.05 mm of being flush with the bottom surface of the mold compound.

8. The semiconductor package of claim 1, wherein a portion of a tie bar couples to and extends away from the die pad and is exposed to an exterior surface of the mold compound.

9. A lead frame strip, comprising:
first, second, third, and fourth dam bars extending in parallel with each other;
a first tie bar coupled to the first and second dam bars;
a second tie bar coupled to the third and fourth dam bars;
a first die pad located in an area between the first and second dam bars and coupled to the first tie bar;
a second die pad located in an area between the third and fourth dam bars and coupled to the second tie bar;
a first lead coupled to the first dam bar and extending toward the first die pad;
a second lead coupled to the second dam bar and extending toward the first die pad, the second lead having a distal end located in a space between the second and third dam bars;
a third lead coupled to the third dam bar and extending toward the second die pad, the third lead having a distal end located in the space between the second and third dam bars, wherein the distal ends of the second and third leads face each other and do not contact each other;
a fourth lead coupled to the fourth dam bar and extending toward the second die pad; and
a connection bar connecting the second and third dam bars to each other.

10. The lead frame strip of claim 9, wherein the second lead has a proximal end opposite the distal end of the second lead, and wherein the proximal end of the second lead is vertically farther away from the second dam bar than is the distal end of the second lead.

11. The lead frame strip of claim 10, wherein the first die pad is vertically the same distance from the second dam bar as is the proximal end of the second lead.

12. The lead frame strip of claim 10, wherein the proximal and distal ends of the second lead are vertically the same distance from the second dam bar.

13. The lead frame strip of claim 9, wherein the distal ends of the second and third leads are copper and are plated with another metal or alloy.

14. The lead frame strip of claim 9, wherein the connection bar is approximately orthogonal to the second and third dam bars.

15. The lead frame strip of claim 9, further comprising a fifth lead coupled to the second dam bar and extending toward the first die pad, the fifth lead having a distal end located in the space between the second and third dam bars, wherein a pitch between the second and fifth leads is less than 2.5 mm.

16. The lead frame strip of claim 9, wherein the distal ends of the second and third leads are separated by a gap ranging from 50 microns to 300 microns.

17. A method of manufacturing a semiconductor package, comprising:
coupling a semiconductor die to a die pad of a lead frame, the die pad in an area between first and second dam bars extending in parallel to each other, the die pad coupled to a tie bar extending between the first and second dam bars, the lead frame including a first lead having a proximal end in the area and a distal end in another area between the second dam bar and a third dam bar extending in parallel with the second dam bar, the distal end of the first lead facing and not touching a distal end of a second lead, the second lead coupled to the third dam bar, a connection bar connecting the second and third dam bars to each other;
wirebonding the semiconductor die to the first lead;
covering the semiconductor die, the die pad, and the proximal end of the first lead with a mold compound;
plating the first and second leads, including the distal ends of the first and second leads; and
trimming the tie bar and the first and second dam bars and cutting the mold compound to produce the semiconductor package.

18. The method of claim 17, wherein a distance between the distal ends of the first and second leads ranges from 50 microns to 300 microns.

19. The method of claim 17, further comprising a third lead extending from the semiconductor package, wherein no lead is positioned in between the first and third leads, and wherein a pitch between the first and third leads is less than 2.5 mm.

20. The method of claim 17, wherein a bottom surface of the first lead is within 0.05 mm of being flush with a bottom surface of the mold compound.
